(19) United States
(12) Patent Application Publication
(10) Pub. No.: US 2026/0344348 A1
(43) Pub. Date: Oct. 29, 2026

(54) Transport Facility

(71) Applicant: Daifuku Co., Ltd., Osaka-shi (JP)

(72) Inventors: Takahiro Sebe, Komaki-shi (JP); Ryosuke Noguchi, Komaki-shi (JP); Makoto Kono, Komaki-shi (JP)

(21) Appl. No.: 19/632,653

(22) Filed: Mar. 30, 2026

(30) Foreign Application Priority Data
Mar. 31, 2025 (JP) 2025-057610

(51) Int. Cl. H10P 72/30; B60L 15/32; B60L 50/53; H10P 72/00; H10P 72/10

(52) U.S. Cl. CPC H10P 72/3214; B60L 15/32; B60L 50/53; H10P 72/0608; H10P 72/1902; H10P 72/1906; H10P 72/3218; B60L 2200/44; B60L 2240/72

(57) ABSTRACT

A transport facility includes a path power feeder. The path power feeder is present in the first transport area and absent in at least a part of a second transport area. A first transport vehicle travels using electric power fed from the path power feeder. A second transport vehicle travels in both the first transport area and the second transport area and receives electric power from the path power feeder. The second transport vehicle includes a power storage that stores electric power fed from the path power feeder. The second transport vehicle travels in the second transport area using the electric power stored in the power storage.

### CROSS-REFERENCE TO RELATED APPLICATION

This application claims priority to Japanese Patent Application No. 2025-057610 filed Mar. 31, 2025, the disclosure of which is hereby incorporated by reference in its entirety.

### BACKGROUND OF THE INVENTION

### Field of the Invention

The present invention relates to a transport facility including a transport vehicle that transports articles and a path power feeder extending along a travel path for the transport vehicle to feed electric power to the transport vehicle on the travel path.

### Description of Related Art

An example of such a transport facility is described in Japanese Unexamined Patent Application Publication No. 2001-218307. In the background described hereafter, reference signs in parentheses are the reference signs in Japanese Unexamined Patent Application Publication No. 2001-218307. The transport facility described in Japanese Unexamined Patent Application Publication No. 2001-218307 includes a transport carriage (24) and a traveling power feeder (27A). The transport carriage (24) travels on a rail (21) housing a feed line (22). The traveling power feeder (27A) applies a high-frequency current to the feed line (22) to feed power to the transport carriage (24) on the rail (21). The transport carriage (24) includes a battery (93) chargeable with electric power fed from the feed line (22) and travels using the battery (93) as a power source in a non-power feed section.

A transport facility may include a first transport vehicle that transports a first article, a second transport vehicle that transports a second article different from the first article, a first transport area in which the first transport vehicle travels to transport the first article, and a second transport area in which the second transport vehicle travels to transport the second article. In this case, both the first transport vehicle and the second transport vehicle are to be driven appropriately using electric power with a lower facility cost. However, Japanese Unexamined Patent Application Publication No. 2001-218307 does not describe such a transport facility.

### SUMMARY OF THE INVENTION

For the transport facility including the first transport vehicle, the second transport vehicle, the first transport area, and the second transport area, techniques for reducing the cost of the facility and driving both the first transport vehicle and the second transport vehicle appropriately using electric power are awaited.

A transport facility according to an aspect of the present disclosure includes at least one first transport vehicle that transports a first article, at least one second transport vehicle that transports a second article different from the first article, a first transport area in which the at least one first transport vehicle travels to transport the first article, a second transport area in which the at least one second transport vehicle travels to transport the second article, and a path power feeder extending along a travel path for the at least one first transport vehicle or the at least one second transport vehicle. The path power feeder feeds power to the at least one first transport vehicle or the at least one second transport vehicle on the travel path. The path power feeder is present in the first transport area and absent in at least a part of the second transport area. The at least one first transport vehicle travels using electric power fed from the path power feeder. The at least one second transport vehicle travels in both the first transport area and the second transport area and receives electric power from the path power feeder. The at least one second transport vehicle includes a power storage that stores electric power fed from the path power feeder. The at least one second transport vehicle travels in the second transport area using the electric power stored in the power storage.

In this structure, the first transport vehicle can be driven on electric power to travel appropriately in the first transport area including the path power feeder. The second transport vehicle that can travel in both the first transport area and the second transport area includes the power storage that stores electric power fed from the path power feeder. The second transport vehicle can thus be driven on electric power to travel appropriately in the second transport area in at least a part of which the path power feeder is not installed, as well as in the first transport area including the path power feeder.

In this manner, this structure can drive both the first transport vehicle and the second transport vehicle by electric power to cause the vehicles to travel appropriately with at least a part of the second transport area not provided with the path power feeder. The transport facility can thus be less costly than a structure in which the entire second transport area is provided with the path power feeder.

In this structure, as described above, the transport facility including the first transport vehicle, the second transport vehicle, the first transport area, and the second transport area can be less costly, and both the first transport vehicle and the second transport vehicle can be driven on electric power to travel appropriately.

Further features and advantageous effects of the transport facility will be apparent from embodiments described below with reference to the drawings.

### BRIEF DESCRIPTION OF THE DRAWINGS

FIG. 1 is a diagram of a transport facility according to an embodiment, illustrating its layout.

FIG. 2 is a diagram of a first transport vehicle and a second transport vehicle in the embodiment.

FIG. 3 is a diagram of a path power feeder in the embodiment;

FIG. 4 is a control block diagram in the embodiment.

### DESCRIPTION OF THE INVENTION

A transport facility according to an embodiment will be described with reference to the drawings. In the figures, components are drawn schematically as appropriate and may or may not be drawn to scale relative to the actual shapes or dimensional ratios.

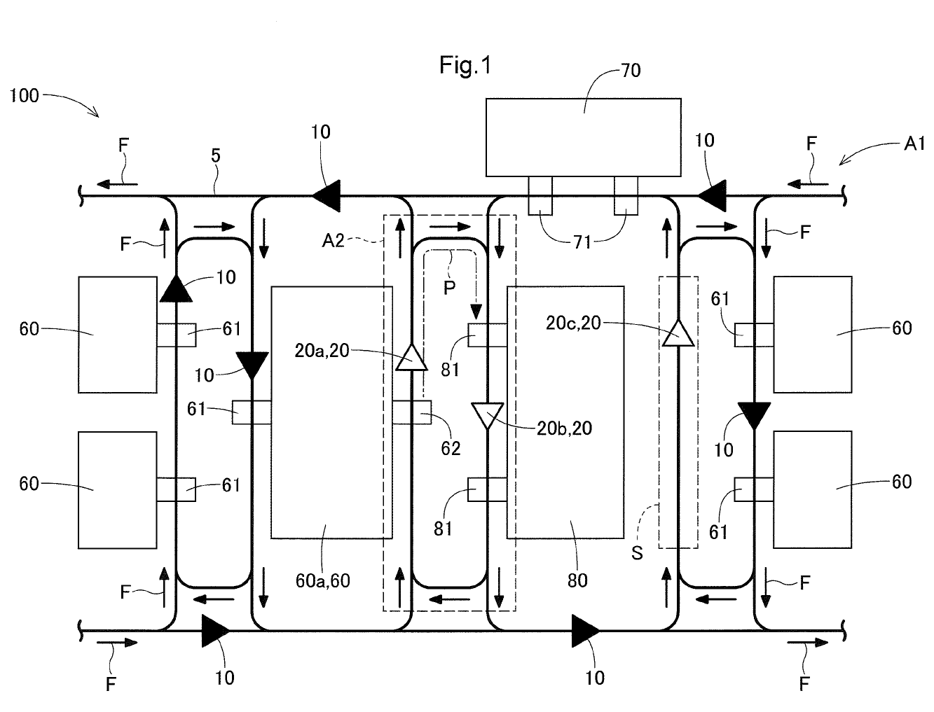

As shown in FIG. 1, a transport facility 100 includes first transport vehicles 10, second transport vehicles 20, a first transport area A1, and a second transport area A2. In the present embodiment, the transport facility 100 includes multiple first transport vehicles 10 and one or more (multiple in this example) second transport vehicles 20. In the present embodiment, the second transport vehicles 20 are fewer than the first transport vehicles 10. The second transport vehicles 20 may be more than or as many as the first transport vehicles 10.

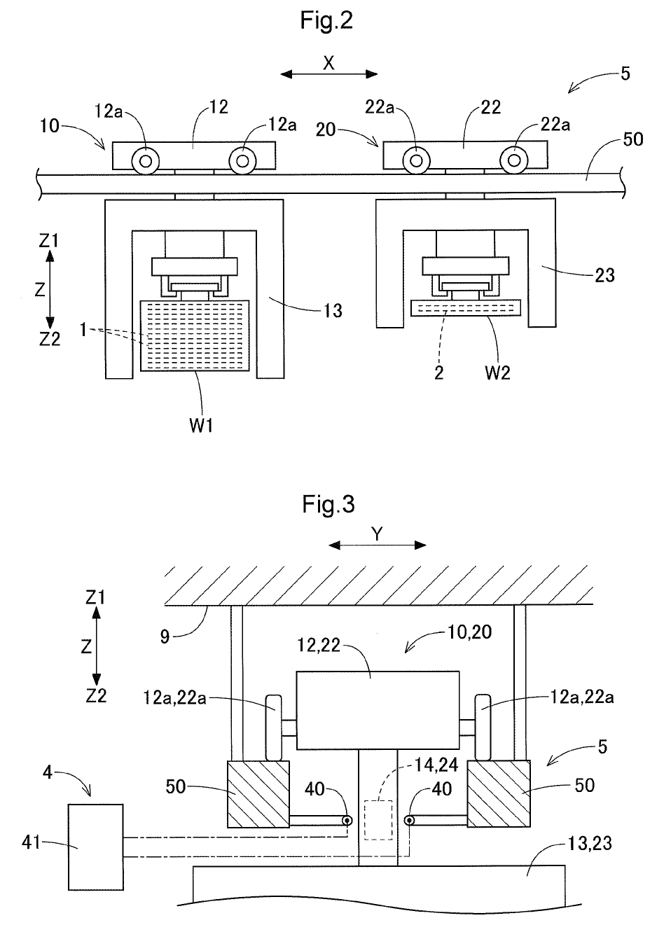

As shown in FIG. 2, the first transport vehicles 10 are each a transport vehicle (an automated guided vehicle in this example) that transports a first article W1. The second transport vehicles 20 are each a transport vehicle (an automated guided vehicle in this example) that transports a second article W2 different from the first article W1. The first article W1 and the second article W2 are different types of articles. In the present embodiment, as shown in FIG. 1, the transport facility 100 includes a first storage device 70 that stores first articles W1 and a second storage device 80 that stores second articles W2. In FIG. 1, an example of the first storage device 70 or the second storage device 80 is a storage device including a loading-unloading portion (loading-unloading port). However, these storage devices (70, 80) may be storage devices with other structures (e.g., storage shelves installed near the ceiling to store articles temporarily).

The first storage device 70 includes first loading-unloading portions 71 for receiving and transferring (more specifically, loading and unloading) the first articles W1. The first storage device 70 stores the first articles W1 received through the first loading-unloading portions 71 and transfers the stored first articles W1 to the first transport vehicles 10 through the first loading-unloading portions 71. The first loading-unloading portions 71 may each be a single first loading-unloading portion 71 used for both loading and unloading or may separately be a first loading-unloading portion 71 for loading and a first loading-unloading portion 71 for unloading.

The second storage device 80 includes second loading-unloading portions 81 for receiving and transferring (more specifically, loading and unloading) the second articles W2. The second storage device 80 stores the second articles W2 received through the second loading-unloading portions 81 and transfers the stored second articles W2 to the second transport vehicles 20 through the second loading-unloading portions 81. The second loading-unloading portions 81 may each be a single second loading-unloading portion 81 for both loading and unloading or may separately be a second loading-unloading portion 81 for loading and a second loading-unloading portion 81 for unloading.

The first articles W1 and the second articles W2 are any types of articles. However, in the present embodiment, each first article W1 is a container that contains semiconductor substrates 1 (semiconductor wafers), and each second article W2 is a container that contains a photoresist mask 2 as shown in FIG. 2. The photoresist mask 2 (e.g., reticle) is used for processing the semiconductor substrates 1 (more specifically, in an exposure process). An example of the first article W1 is a front opening unified pod (FOUP). An example of the second article W2 is a reticle pod.

In the present embodiment, as shown in FIG. 1, the transport facility 100 includes processing devices 60 that perform processing (e.g., thin film formation or etching) on the semiconductor substrates 1. The processing devices 60 each include a first port 61 to receive and transfer the first articles W1. Each processing device 60 performs processing on the semiconductor substrates 1 unloaded from the first articles W1, which have been received through the first port 61. The processing device 60 transfers the first article W1 containing the processed semiconductor substrates 1 to the first transport vehicle 10 through the first port 61.

In the present embodiment, the transport facility 100 includes multiple processing devices 60. The multiple processing devices 60 include an exposure processing device 60a that performs an exposure process on the semiconductor substrates 1 using the photoresist mask 2. The exposure processing device 60a includes, in addition to the first port 61, a second port 62 to receive and transfer the second articles W2. The exposure processing device 60a performs the exposure process on the semiconductor substrates 1 unloaded from the first articles W1, which have been received through the first port 61, using the photoresist mask 2 unloaded from the second articles W2, which have been received through the second port 62. The exposure processing device 60a transfers the first articles W1 containing the semiconductor substrates 1 that have undergone the exposure process to the first transport vehicle 10 through the first port 61. The exposure processing device 60a also transfers the second articles W2 containing the photoresist masks 2 used to process the semiconductor substrates 1 to the second transport vehicle 20 through the second port 62.

The first transport area A1 is an area in which the first transport vehicles 10 travel to transport the first articles W1. More specifically, the first transport vehicles 10 travel at least in the first transport area A1 to transport the first articles W1. The second transport area A2 is an area in which the second transport vehicles 20 travel to transport the second articles W2. More specifically, the second transport vehicles 20 travel at least in the second transport area A2 to transport the second articles W2. The first transport area A1 and the second transport area A2 are different from each other. In FIG. 1, the area other than the second transport area A2 is the first transport area A1.

The first transport vehicles 10 are each assigned to a first transport task specifying the source and the destination of a first article W1. The first transport vehicle 10 assigned to the first transport task performs the first transport task. More specifically, the first transport vehicle 10 travels to the source specified in the first transport task to receive the first article W1 from the source, and then travels to the destination specified in the first transport task to transfer the first article W1 to the destination. In this manner, the first transport task or a second transport task (described later) includes movement from the current position to the source and movement from the source to the destination. In the present embodiment, the first ports 61 included in the processing devices 60 or the first loading-unloading portions 71 included in the first storage device 70 are specified as the sources or the destinations of the first articles W1.

In the present embodiment, the first transport vehicles 10 travel in the first transport area A1 alone to transport the first articles W1. The sources and the destinations of the first articles W1 are all set in the first transport area A1. In the present embodiment, as shown in FIG. 2, the first transport vehicle 10 is larger than the second transport vehicle 20 in a vertical direction Z. A portion of the first transport vehicle 10 in a lower side Z2 may interfere with a device included in the second transport area A2. In the present embodiment, the first transport vehicles 10 are thus prohibited from entering the second transport area A2 and travel in the first transport area A1 alone. In some embodiments, for example, the first transport vehicles 10 may be prohibited from entering the second transport area A2 in which no transport requests are generated for the first transport vehicles 10, and thus travel in the first transport area A1 alone.

The second transport vehicles 20 are each assigned to a second transport task specifying the source and the destination of a second article W2. The second transport vehicle 20 assigned to the second transport task performs the second transport task. More specifically, the second transport vehicle 20 travels to the source specified in the second transport task to receive the second article W2 from the source, and then travels to the destination specified in the second transport task to transfer the second article W2 to the destination. In the present embodiment, the second port 62 included in the exposure processing device 60a or the second loading-unloading portions 81 included in the second storage device 80 are specified as the sources or the destinations of the second articles W2.

In the present embodiment, the sources and the destinations of the second articles W2 are all set in the second transport area A2. The second transport vehicles 20 thus travel in, for example, the second transport area A2 alone to transport the second articles W2. The second transport vehicles 20 can travel in both the first transport area A1 and the second transport area A2. More specifically, the first transport area A1 and the second transport area A2 are connected to allow the second transport vehicles 20 to move between the first transport area A1 and the second transport area A2. The second transport vehicles 20 can thus travel in the first transport area A1 in addition to the second transport area A2 to transport the second articles W2. The second transport vehicles 20 transporting the second articles W2 travel in the first transport area A1 in addition to the second transport area A2 to, for example, avoid congestion.

The transport facility 100 may include no second storage device 80. The second articles W2 may be stored in the first storage device 70 in the same manner as the first articles W1. In this case, the second transport vehicles 20 travel in the first transport area A1 and the second transport area A2 to transport the second articles W2 between the first storage device 70 (more specifically, the first loading-unloading portion 71) and the exposure processing device 60a (more specifically, the second port 62).

In the present embodiment, the first transport vehicles 10 and the second transport vehicles 20 travel along a preset travel path 5. The travel path 5 is a set of multiple paths (point-to-point paths connecting points). The first transport vehicles 10 travel on the travel path 5 in the first transport area A1. The second transport vehicles 20 travel on the travel path 5 in the second transport area A2. The travel path 5 in the first transport area A1 is connected to the travel path 5 in the second transport area A2 to allow the second transport vehicles 20 to move between the first transport area A1 and the second transport area A2. The second transport vehicles 20 can thus also travel on the travel path 5 in the first transport area A1 (the travel path 5 for the first transport vehicles 10). As shown in FIG. 1, a forward direction F is defined for various parts of the travel path 5. The first transport vehicles 10 and the second transport vehicles 20 basically travel on the various parts of the travel path 5 in the forward direction F. The travel path 5 shown in FIG. 1 includes junctions at which multiple paths merge into a single path and branches at which a single path branches into multiple paths. The travel path 5 for the first transport vehicles 10 in the first transport area A1 has a total length referred to as a first travel path length. The travel path 5 for the second transport vehicles 20 in the second transport area A2 has a total length referred to as a second travel path length. In the present embodiment, the second travel path length is shorter than the first travel path length. In some embodiments, the second travel path length may be greater than or equal to the first travel path length.

As shown in FIG. 2, the travel path 5 in the present embodiment is defined by rails 50. The direction along the travel path 5 is referred to as a front-rear direction X. The direction perpendicular to both the front-rear direction X and the vertical direction Z is referred to as a lateral direction Y. In the present embodiment, the travel path 5 is defined by a pair of rails 50 spaced from each other in the lateral direction Y as shown in FIG. 3. In the present embodiment, the first transport vehicles 10 and the second transport vehicles 20 have the same basic structure. The reference numerals for the first transport vehicles 10 and the second transport vehicles 20 are shown side by side in FIG. 3.

In the present embodiment, the rails 50 are hung from a ceiling 9. In the present embodiment, the first transport vehicles 10 and the second transport vehicles 20 are ceiling-hung transport vehicles that travel along the travel path 5 defined along the ceiling 9. The travel path 5 may be defined on, for example, the floor surface, rather than along the ceiling 9. The travel path 5 may be defined without using the rails 50 and may be defined to, for example, connect multiple detectable members (e.g., two-dimensional codes or wireless tags) installed on, for example, the floor surface.

The first transport vehicles 10 are driven on electric power to travel along the travel path 5. More specifically, each first transport vehicle 10 includes a first traveler 12 that is driven on electric power to travel along the travel path 5 as shown in FIG. 2. In the example shown in FIG. 2, the first traveler 12 includes multiple first travel wheels 12a that roll on the rails 50. At least one of the first travel wheels 12a is driven by an unillustrated electric drive (e.g., an electric motor such as a servo motor, the same applies hereafter) to rotate, causing the first traveler 12 to travel along the rails 50.

The first transport vehicles 10 driven on electric power transfer the first articles W1 to and from a transfer area (e.g., the first port 61 or the first loading-unloading portion 71). More specifically, each first transport vehicle 10 includes a first transferrer 13 that is driven on electric power to transfer the first article W1 as shown in FIG. 2. The first transferrer 13 is connected to the first traveler 12. In this example, the first traveler 12 is disposed in an upper side Z1 relative to the first transferrer 13.

Although not described in detail, the first transferrer 13 in the example shown in FIG. 2 includes a first holder that holds the first article W1 and a first lifter that lifts and lowers the first holder with respect to the first traveler 12. The first holder is driven by an electric drive (not shown) to perform a holding operation of holding the first article W1 and a releasing operation of releasing the first article W1. The first lifter is driven by an electric drive (not shown) to perform a lowering operation of lowering the first holder to the transfer area and a lifting operation of lifting the first holder from the transfer area.

When the first transferrer 13 with the first holder holding a first article W1 (refer to FIG. 2) transfers the first article W1 to the transfer area, the first lifter performs the lowering operation. The first holder then performs the releasing operation, and the first lifter performs the lifting operation. When the first transferrer 13 with the first holder holding no first article W1 receives the first article W1 from the transfer area, the first lifter performs the lowering operation. The first holder then performs the holding operation, and the first lifter performs the lifting operation.

The second transport vehicles 20 are driven on electric power to travel along the travel path 5. More specifically, each second transport vehicle 20 includes a second traveler 22 that is driven on electric power to travel along the travel path 5 as shown in FIG. 2. In the example shown in FIG. 2, the second traveler 22 includes multiple second travel wheels 22a that roll on the rails 50. At least one of the second travel wheels 22a is driven by an electric drive (not shown) to rotate, causing the second traveler 22 to travel along the rails 50.

The second transport vehicle 20 driven on electric power transfers the second article W2 to and from a transfer area (e.g., the second port 62 or the second loading-unloading portion 81). More specifically, the second transport vehicle 20 includes a second transferrer 23 that is driven on electric power to transfer the second article W2 as shown in FIG. 2. The second transferrer 23 is connected to the second traveler 22. In this example, the second traveler 22 is disposed in the upper side Z1 relative to the second transferrer 23.

Although not described in detail, the second transferrer 23 in the example shown in FIG. 2 includes a second holder that holds the second article W2 and a second lifter that lifts and lowers the second holder with respect to the second traveler 22. The second holder is driven by an electric drive (not shown) to perform a holding operation of holding the second article W2 and a releasing operation of releasing the second article W2. The second lifter is driven by an electric drive (not shown) to perform a lowering operation of lowering the second holder to the transfer area and a lifting operation of lifting the second holder from the transfer area.

When the second transferrer 23 with the second holder holding a second article W2 (refer to FIG. 2) transfers the second article W2 to the transfer area, the second lifter performs the lowering operation. The second holder then performs the releasing operation, and the second lifter performs the lifting operation. When the second transferrer 23 with the second holder holding no second article W2 receives the second article W2 from the transfer area, the second lifter performs the lowering operation. The second holder then performs the holding operation, and the second lifter performs the lifting operation.

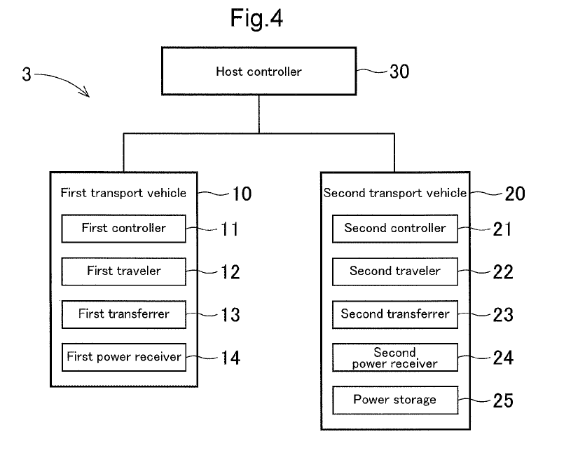

The transport facility 100 includes a control system 3 (refer to FIG. 4) that controls the second transport vehicles 20. The control system 3 also controls the first transport vehicles 10. In the present embodiment, as shown in FIG. 4, the control system 3 includes a first controller 11 included in each first transport vehicle 10, a second controller 21 included in each second transport vehicles 20, and a host controller 30 that can communicate with the first controller 11 and the second controller 21. Each of these controllers (11, 21, 30) includes an arithmetic processor such as a microcomputer and peripheral circuits such as a memory. The functions of each controller are implemented by hardware such as the arithmetic processor and a program executed on the hardware cooperating with each other.

The control system 3 (more specifically, the host controller 30) tracks the current positions of the multiple first transport vehicles 10 and the multiple second transport vehicles 20. In the present embodiment, each first transport vehicle 10 determines its current position, and each second transport vehicle 20 determines its current position. The host controller 30 obtains information indicating the current positions of the first transport vehicles 10 from the first transport vehicles 10 and information indicating the current positions of the second transport vehicles 20 from the second transport vehicles 20.

The control system 3 (more specifically, the host controller 30) performs a first task assignment process for assigning a first transport vehicle 10 to a first transport task specifying the source and the destination of a first article W1. The first controller 11 in the first transport vehicle 10 assigned to the first transport task controls the first transport vehicle 10 to perform the first transport task. The control system 3 (more specifically, the host controller 30) also performs a second task assignment process for assigning a second transport vehicle 20 to a second transport task specifying the source and the destination of a second article W2. The second controller 21 in the second transport vehicle 20 assigned to the second transport task controls the second transport vehicle 20 to perform the second transport task.

In FIG. 1, the second transport vehicle 20 with the reference numeral 20a is a second transport vehicle 20 performing a second transport task specifying the second port 62 of the exposure processing device 60a as the source and the second loading-unloading portion 81 of the second storage device 80 as the destination. The path P in FIG. 1 indicates a transport path for the second article W2 involved in this second transport task. In the present embodiment, the second transport task corresponds to a transport task, and the second task assignment process corresponds to a task assignment process.

The transport facility 100 includes a path power feeder 4 (refer to FIG. 3). Although not shown in FIGS. 1 and 2, the path power feeder 4 extends along the travel path 5 for the first transport vehicles 10 or the second transport vehicles 20. More specifically, the path power feeder 4 includes power feed portions (feed lines 40 described later in the present embodiment) extending along the travel path 5. The path power feeder 4 feeds electric power to the first transport vehicles 10 or the second transport vehicles 20 on the travel path 5. The path power feeder 4 can feed power to the first transport vehicles 10 or the second transport vehicles 20 at any position in a section of the travel path 5 including the path power feeder 4. The path power feeder 4 can feed power to both a stationary first transport vehicle 10 and a traveling first transport vehicle 10 as well as both a stationary second transport vehicle 20 and a traveling second transport vehicle 20. In this manner, the path power feeder 4 is a device extending along the travel path 5 to feed power to a transport vehicle at any position on the travel path 5, rather than a device disposed at a specific position on the travel path 5 to feed power to a stationary transport vehicle.

As shown in FIG. 3, the path power feeder 4 includes the feed lines 40 extending along the travel path 5, and a power supply 41 that supplies power to the feed lines 40. In the present embodiment, the feed lines 40 are arranged along the rails 50 defining the travel path 5. More specifically, a pair of feed lines 40 spaced in the lateral direction Y are arranged along the pair of rails 50.

The feed lines 40 may feed power to the first transport vehicles 10 or the second transport vehicles 20 with contact or contactlessly. In the present embodiment, the feed lines 40 contactlessly feed power to the first transport vehicles 10 or the second transport vehicles 20. The feed lines 40 as induction lines feed power to the first transport vehicles 10 or the second transport vehicles 20.

As shown in FIGS. 3 and 4, each first transport vehicle 10 includes a first power receiver 14 that receives power from the path power feeder 4. Each second transport vehicle 20 includes a second power receiver 24 that receives power from the path power feeder 4. In the present embodiment, as shown in FIG. 3, the first power receiver 14 is included in a portion connecting the first traveler 12 and the first transferrer 13, and the second power receiver 24 is included in a portion connecting the second traveler 22 and the second transferrer 23. In the present embodiment, the first power receiver 14 or the second power receiver 24 disposed between the pair of feed lines 40 contactlessly receives power from the pair of feed lines 40. The first power receiver 14 and the second power receiver 24 each include, for example, a pickup coil. In the pickup coil, alternating current power is induced by a magnetic field generated around the feed lines 40 receiving alternating current. The alternating current power is converted to, for example, direct current power, and used to drive the first transport vehicle 10 or the second transport vehicle 20.

The transport facility 100 includes the path power feeder 4 in the first transport area A1. More specifically, the path power feeder 4 extends along the travel path 5 in the first transport area A1 (the travel path 5 for the first transport vehicles 10). Although a part of the travel path 5 such as the junctions or the branches described above may include no path power feeder 4, the path power feeder 4 extends throughout the travel path 5 in the first transport area A1. In the present embodiment, the second transport area A2 includes no path power feeder 4 as described later. In the present embodiment, the area including the path power feeder 4 is the first transport area A1.

The first transport vehicles 10 can travel using electric power fed from the path power feeder 4. More specifically, each first transport vehicle 10 travels with the first traveler 12 being driven by electric power received by the first power receiver 14 from the path power feeder 4. The first transport vehicle 10 can transfer the first article W1 to and from the transfer area using electric power fed from the path power feeder 4. More specifically, the first transferrer 13 is driven by the electric power received by the first power receiver 14 from the path power feeder 4 to transfer the first article W1 between the first transport vehicle 10 and the transfer area.

As described later, the second transport vehicles 20 each include a power storage 25 that stores electric power fed from the path power feeder 4. In the present embodiment, the first transport vehicles 10 include no power storage that stores electric power fed from the path power feeder 4. In this example, including no power storage refers to including no power storage with a capacity for storing electric power for normal traveling on the travel path 5. The first transport vehicles 10 may thus each include a power storage (low-capacity power storage) for short-distance traveling in, for example, an emergency situation in which the first transport vehicle 10 can receive no electric power from the path power feeder 4 due to, for example, a failure.

The second transport vehicles 20 can receive electric power fed from the path power feeder 4 (the path power feeder 4 included in the first transport area A1 in the present embodiment). As shown in FIG. 4, each second transport vehicle 20 includes the power storage 25 that stores electric power fed from the path power feeder 4. The power storage 25 has a capacity for storing electric power for normal traveling on the travel path 5. The power storage 25 can be charged and discharged. The power storage 25 may be, for example, a battery, a capacitor, or a combination of a battery and a capacitor. The power storage 25 includes a battery level sensor to detect a battery level. The battery level sensor includes, for example, one or both of a voltage sensor and a current sensor.

In the transport facility 100, at least a part of the second transport area A2 includes no path power feeder 4. In the present embodiment, the second transport area A2 includes no path power feeder 4. More specifically, the travel path 5 in the second transport area A2 (the travel path 5 for the second transport vehicle 20) includes no path power feeder 4. Each second transport vehicle 20 can travel in the second transport area A2 using the electric power stored in the power storage 25. More specifically, the second transport vehicle 20 travels with the second traveler 22 being driven by the electric power stored in the power storage 25. The second transport vehicle 20 can transfer the second article W2 to and from the transfer area in the second transport area A2 using the electric power stored in the power storage 25. More specifically, the second transferrer 23 is driven by the electric power stored in the power storage 25 to transfer the second article W2 between the second transport vehicle 20 and the transfer area.

As described above, the second transport vehicles 20 each travel in the second transport area A2 using the electric power stored in the power storage 25. The upper limit of the travel speed set for the second transport vehicle 20 with the power storage 25 having a battery level lower than the first set value can be lower than the upper limit for the second transport vehicle 20 with the power storage 25 having a battery level higher than or equal to the first set value. The battery level of the power storage 25 in a traveling second transport vehicle 20 is thus less likely to be insufficient. The second transport area A2 including no path power feeder 4 may include a power feeder (power feed station) that feeds electric power to a stationary second transport vehicle 20 (more specifically, the power storage 25) at a specific site on the travel path 5 in the second transport area A2 to charge the power storage 25. The power storage 25 can also be charged using regenerative power resulting from deceleration of the second transport vehicle 20 in the second transport area A2 including no path power feeder 4.

As described above, the transport facility 100 includes no path power feeder 4 in at least a part of the second transport area A2. At least a part of the travel path 5 in the second transport area A2 may thus include no path power feeder 4 (no feed lines 40 in the present embodiment). This structure can reduce the cost of the transport facility 100 and shorten the construction period. In the transport facility 100, the first transport vehicles 10 may include no power storage that stores electric power fed from the path power feeder 4. This structure can also reduce the cost of the transport facility 100. The layout (the layout of the travel path 5) can also be easily changed in the part of the second transport area A2 including no path power feeder 4. These advantages are more notable particularly when the second transport area A2 (the entire second transport area A2) includes no path power feeder 4.

The second transport vehicles 20 can travel in a section of the travel path 5 including the path power feeder 4 (the travel path 5 in the first transport area A1 in the present embodiment) using at least one of the electric power fed from the path power feeder 4 or the electric power stored in the power storage 25. More specifically, each second transport vehicle 20 travels with the second traveler 22 being driven by at least one of the power received by the second power receiver 24 from the path power feeder 4 or the electric power stored in the power storage 25. In the section of the travel path 5 including the path power feeder 4, the second transport vehicle 20 can transfer the second article W2 to and from the transfer area using at least one of the electric power fed from the path power feeder 4 or the electric power stored in the power storage 25. More specifically, the second transferrer 23 is driven by at least one of the power received by the second power receiver 24 from the path power feeder 4 or the electric power stored in the power storage 25 to transfer the second article W2 between the second transport vehicle 20 and the transfer area.

A power storage 25 to be charged may be charged while the corresponding second transport vehicle 20 is traveling on the section of the travel path 5 including the path power feeder 4. In this case, the second transport vehicle 20 may travel at a lower travel speed to use more electric power fed from the path power feeder 4 for charging the power storage 25. The upper limit of the travel speed for the second transport vehicle 20 can thus be lower in a stepwise manner or continuously as the battery level of the power storage 25 decreases, for example.

As described above, the control system 3 (more specifically, the host controller 30, the same applies hereafter) performs the second task assignment process for assigning a second transport vehicle 20 to a second transport task specifying the source and the destination of a second article W2. More specifically, the control system 3 obtains the battery level of the power storage 25 in each second transport vehicle 20. The battery level is, for example, a ratio (percentage) of the remaining capacity to a full charge capacity. In this case, the battery level in a fully charged state is 100%, and the battery level in a fully discharged state is 0%. The battery level of the power storage 25 can be estimated based on, for example, the output voltage of the power storage 25, the integrated value of the power amount charged to the power storage 25 and the integrated value of the power amount discharged from the power storage 25, or a combination of these.

The control system 3 does not assign, to a second transport task, the second transport vehicle 20 with the power storage 25 having a battery level lower than a second set value. In other words, the control system 3 assigns, to a second transport task, the second transport vehicle 20 with the power storage 25 having a battery level higher than or equal to the second set value. The battery level of the power storage 25 to be compared with the second set value may be the battery level at the time the second transport vehicle 20 is assigned to the second transport task or the battery level (predicted value) at the time the second transport vehicle 20 completes the second transport task. The battery level at the completion of the second transport task can be predicted by, for example, predicting the amount of power to be consumed for the second transport task based on, for example, past performance.

In the present embodiment, the control system 3 performs a charge process for moving the second transport vehicle 20 assigned to no second transport task to a site including the path power feeder 4 (a site in the first transport area A1 in the present embodiment) and charging the power storage 25 using the path power feeder 4. When the power storage 25 is charged, the second transport vehicle 20 waits at the site or moves to another site (e.g., a site in the second transport area A2 including no path power feeder 4) to wait. The second transport vehicle 20 moving to another site moves to a site in the second transport area A2 including no path power feeder 4 to wait through, for example, a standby process described later.

In the present embodiment, as shown in FIG. 1, the first transport area A1 includes a standby section S in which the second transport vehicles 20 can wait. The control system 3 moves the second transport vehicles 20 to the standby section S in the charge process. The second transport vehicle 20 with the reference numeral 20c in FIG. 1 is a second transport vehicle 20 that has moved to the standby section S to charge the power storage 25 in the standby section S in the charge process. The standby section S is defined in the first transport area A1. The standby section S may thus be defined in a site that is less likely to affect the transport efficiency of the first transport vehicles 10 transporting the first articles W1.

The standby section S may be defined in a site in which the first transport vehicles 10 travel or in a site in which no first transport vehicles 10 travel. When the standby section S is defined in a site in which the first transport vehicles 10 travel, the control system 3 controls the first transport vehicles 10 to allow no first transport vehicles 10 to travel in the standby section S at least when, for example, a second transport vehicle 20 is waiting in the standby section S. In some embodiments, the first transport vehicles 10 travel in the standby section S. In this case, the control system 3 may control the second transport vehicles 20 to move the second transport vehicle 20 waiting in the standby section S to a site in which the second transport vehicle 20 does not obstruct the traveling of the first transport vehicles 10. The standby section S defined in a site in which no first transport vehicles 10 travel is a dedicated section for waiting and charging of the second transport vehicles 20. In this case, the control system 3 controls the first transport vehicles 10 to allow no first transport vehicles 10 to travel in the standby section S.

In the present embodiment, the control system 3 performs a battery level determination process to determine whether the battery level of the power storage 25 in a second transport vehicle 20 is higher than or equal to a third set value. When the control system 3 determines that the battery level of the power storage 25 in the second transport vehicle 20 assigned to no second transport task is higher than or equal to the third set value, the control system 3 performs the standby process to cause the second transport vehicle 20 to wait at a site in the second transport area A2 including no path power feeder 4. In this case, the control system 3 performs the standby process, in place of the charge process, for the second transport vehicle 20 assigned to no second transport task. In the present embodiment, the second transport area A2 includes no path power feeder 4. In the present embodiment, every site in the second transport area A2 can basically be a standby site for the second transport vehicles 20 in the standby process. The second transport vehicle 20 with the reference numeral 20b in FIG. 1 is a second transport vehicle 20 waiting in the second transport area A2 in the standby process.

In the present embodiment, the control system 3 assigns the second transport vehicle 20 with the power storage 25 having a battery level higher than or equal to the second set value to a second transport task as described above. With the second transport vehicle 20 waiting in the standby process, the generated second transport task is assigned to the waiting second transport vehicle 20 and is thus promptly started. In the present embodiment, the third set value is set to the same value as or a value greater than the second set value. In the present embodiment, the third set value corresponds to a set value.

A no-standby section in which no second transport vehicles 20 can wait may be defined. In this case, the control system 3 causes the second transport vehicle 20 assigned to no second transport task to wait at a site (e.g., the standby section S) other than the no-standby section. For example, the entire second transport area A2 can be the no-standby section.

In the present embodiment, the second transport area A2 includes no path power feeder 4. The path power feeder 4 can thus be downscaled compared with the structure in which the second transport area A2 includes the path power feeder 4. However, the second transport vehicles 20 are driven on electric power in the second transport area A2. Each second transport vehicle 20 is thus to include the power storage 25. To reduce the cost of the transport facility 100, the cost reduction resulting from downscaling the path power feeder 4 may exceed the cost increase resulting from installing the power storages 25 on the second transport vehicles 20.

For achieving the cost reduction, the value resulting from dividing the second travel path length by the number of second transport vehicles 20 may be greater than the value resulting from dividing the first travel path length by the number of first transport vehicles 10, where the first travel path length is the total length of the travel path 5 for the first transport vehicles 10 in the first transport area A1 and the second travel path length is the total length of the travel path 5 for the second transport vehicles 20 in the second transport area A2. In other words, the second transport vehicles 20 per unit length of the travel path 5 in the second transport area A2 may be fewer than the first transport vehicles 10 per unit length of the travel path 5 in the first transport area A1. In this structure, the cost reduction resulting from downscaling the path power feeder 4 is likely to exceed the cost increase resulting from installing the power storages 25 on the second transport vehicles 20.

The cost reduction resulting from downscaling the path power feeder 4 exceeds the cost increase resulting from installing the power storages 25 on the second transport vehicles 20 in other structures. In a structure with a high installation cost of the path power feeder 4 per unit length of the travel path 5, for example, the cost reduction resulting from downscaling the path power feeder 4 can exceed the cost increase resulting from installing the power storages 25 on the second transport vehicles 20 although the second travel path length is shorter (e.g., shorter than the first travel path length). In particular, for a structure in which the second article W2 is a container containing the photoresist mask 2 as in the present embodiment, the layout of the travel path 5 for the second transport vehicles 20 in the second transport area A2 may be complex. This may increase the installation cost of the path power feeder 4 per unit length of the travel path 5 in the second transport area A2. In the present embodiment, the cost reduction resulting from downscaling the path power feeder 4 is thus likely to exceed the cost increase resulting from installing the power storages 25 on the second transport vehicles 20 although the second travel path length is shorter than the first travel path length.

### Other Embodiments

(1) In the above embodiment, the second transport area A2 includes no path power feeder 4. However, the present disclosure is not limited to this structure. A part of the second transport area A2 may include the path power feeder 4. More specifically, the path power feeder 4 may extend along a part of the travel path 5 in the second transport area A2 (the travel path 5 for the second transport vehicles 20). In this case, the second transport vehicles 20 can receive power from the path power feeder 4 included in the first transport area A1 and from the path power feeder 4 included in the second transport area A2.
(2) In the above embodiment, the first transport area A1 includes the standby section S, and the control system 3 moves the second transport vehicles 20 to the standby section S in the charge process. However, the present disclosure is not limited to this structure. The first transport area A1 may include no standby section S. The site to which the second transport vehicles 20 are moved in the charge process may be a site that is less likely to affect the transport efficiency of the first transport vehicles 10 transporting the first articles W1. Such a site is defined based on the state of the first transport area A1 at the time of the charge process. When a part of the second transport area A2 includes the path power feeder 4, the second transport vehicle 20 in the charge process may move to a site in the second transport area A2.
(3) In the above embodiment, the control system 3 performs the standby process to cause the second transport vehicle 20 assigned to no second transport task to wait at a site in the second transport area A2 including no path power feeder 4, in response to determining the battery level of the power storage 25 in the second transport vehicle 20 is higher than or equal to the third set value. However, the present disclosure is not limited to this structure. The control system 3 may perform, as the standby process, a process for causing the second transport vehicle 20 to wait at a site in the second transport area A2 including the path power feeder 4 or a site in the first transport area A1. The control system 3 may perform the charge process independently of whether the battery level of the power storage 25 in the second transport vehicle 20 assigned to no second transport task is higher than or equal to the third set value. In this case, the power storage 25 in the second transport vehicle 20 that has moved to a site including the path power feeder 4 in the charge process is not charged unless the power storage 25 is to be charged. The second transport vehicle 20 waits at the site.
(4) In the above embodiment, the control system 3 includes the first controller 11, the second controller 21, and the host controller 30. However, the present disclosure is not limited to this structure. The control system 3 may include the host controller 30 alone. The transport facility 100 may include no host controller 30, and the first controller 11 and the second controller 21 that can communicate with each other may cooperate to implement the control system 3.
(5) The structure described in each of the above embodiments may be combined with the structures described in other embodiments (including combinations of the other embodiments described as other embodiments) unless any contradiction arises. For other structures as well, the embodiments described herein are merely illustrative in all aspects. Thus, the embodiments may be modified variously as appropriate without departing from the spirit and scope of the disclosure.

### Overview of Present Embodiment

An overview of the transport facility according to the embodiments described above is provided below.

A transport facility includes at least one first transport vehicle that transports a first article, at least one second transport vehicle that transports a second article different from the first article, a first transport area in which the at least one first transport vehicle travels to transport the first article, a second transport area in which the at least one second transport vehicle travels to transport the second article, and a path power feeder extending along a travel path for the at least one first transport vehicle or the at least one second transport vehicle. The path power feeder feeds power to the at least one first transport vehicle or the at least one second transport vehicle on the travel path. The path power feeder is present in the first transport area and absent in at least a part of the second transport area. The at least one first transport vehicle travels using electric power fed from the path power feeder. The at least one second transport vehicle travels in both the first transport area and the second transport area and receives electric power from the path power feeder. The at least one second transport vehicle includes a power storage that stores electric power fed from the path power feeder. The at least one second transport vehicle travels in the second transport area using the electric power stored in the power storage.

In this structure, the first transport vehicle can be driven on electric power to travel appropriately in the first transport area including the path power feeder. The second transport vehicle that can travel in both the first transport area and the second transport area includes the power storage that stores electric power fed from the path power feeder. The second transport vehicle can thus be driven on electric power to travel appropriately in the second transport area in at least a part of which the path power feeder is not installed, as well as in the first transport area including the path power feeder.

In this manner, this structure can drive both the first transport vehicle and the second transport vehicle by electric power to cause the vehicles to travel appropriately with at least a part of the second transport area not provided with the path power feeder. The transport facility can thus be less costly than a structure in which the entire second transport area is provided with the path power feeder.

In this structure, as described above, the transport facility including the first transport vehicle, the second transport vehicle, the first transport area, and the second transport area can be less costly, and both the first transport vehicle and the second transport vehicle can be driven on electric power to travel appropriately.

The transport facility may further include a control system that controls the at least one second transport vehicle. The control system may perform a task assignment process for assigning to the at least one second transport vehicle a transport task specifying a source of the second article and a destination of the second article, and a charge process for causing the at least one second transport vehicle to which no transport task has been assigned to move to a site in which the path power feeder is present and causing the path power feeder to charge the power storage.

In this structure, the power storage in the second transport vehicle can be charged using the time in which the second transport vehicle is not assigned to a transport task. This may increase the transport efficiency of the second transport vehicle transporting the second article.

In the above structure in which the control system performs the task assignment process and the charge process, the first transport area may include a standby section for the at least one second transport vehicle to wait. The control system may cause the at least one second transport vehicle to which no transport task has been assigned to move to the standby section in the charge process.

In this structure, the second transport vehicle can wait or the power storage in the second transport vehicle can be charged appropriately in the standby section defined in the first transport area. The second transport vehicle waits in the standby section defined in the first transport area rather than at a site in the first transport area. The second transport vehicle is less likely to obstruct the first transport vehicle transporting the first article.

The control system may determine whether a battery level of the power storage is higher than or equal to a set value, and may cause the at least one second transport vehicle to which no transport task has been assigned to wait at the part of the second transport area in response to determining that the battery level of the power storage of the at least one second transport vehicle to which no transport task has been assigned is higher than or equal to the set value.

In this structure, the second transport vehicle can wait in the second transport area when the power storage is less likely to be charged. The transport task involving the second article can thus be promptly started when the transport task is generated. This can increase the transport efficiency of the second transport vehicle transporting the second article.

In the transport facility having the structures described above, the at least one first transport vehicle may include a plurality of first transport vehicles, and the at least one second transport vehicle may include a plurality of second transport vehicles. A value resulting from dividing a second travel path length by a number of the plurality of second transport vehicles may be greater than a value resulting from dividing a first travel path length by a number of the plurality of first transport vehicles, where the first travel path length is a total length of the travel path for the plurality of first transport vehicles in the first transport area, and the second travel path length is a total length of the travel path for the plurality of second transport vehicles in the second transport area.

In the transport facility according to one or more embodiments of the present disclosure, the path power feeder can be downscaled compared with the path power feeder in a structure in which the entire second transport area includes the path power feeder. However, the second transport vehicles are to include the power storages. In the above structure, the value resulting from dividing the second travel path length by the number of second transport vehicles is greater than the value resulting from dividing the first travel path length by the number of first transport vehicles. The cost reduction resulting from downscaling the path power feeder is thus likely to exceed the cost increase resulting from installing the power storage on the second transport vehicle. The transport facility may thus be less costly.

The at least one first transport vehicle may include a plurality of first transport vehicles. The at least one second transport vehicle may include one or more second transport vehicles. The one or more second transport vehicles may be fewer than the plurality of first transport vehicles.

In this structure, fewer second transport vehicles are to include the power storages. This can reduce the cost increase resulting from installing the power storages on the second transport vehicles, and the transport facility may be less costly.

A second travel path length may be shorter than a first travel path length, where the first travel path length is a total length of the travel path for the at least one first transport vehicle in the first transport area, and the second travel path length is a total length of the travel path for the at least one second transport vehicle in the second transport area.

In this structure, a shorter path may extend from a site in the second transport area including no path power feeder to a site including the path power feeder (e.g., a site in the first transport area). Thus, the battery level of the power storage in the second transport vehicle moving to a site including the path power feeder to charge the power storage is less likely to be insufficient.

The first article may be a container configured to contain a semiconductor substrate. The second article may be a container configured to contain a photoresist mask for use to process the semiconductor substrate.

As in this structure, when the first article is the container configured to contain a semiconductor substrate, and the second article is the container configured to contain a photoresist mask, the second transport vehicles tend to be fewer than the first transport vehicles. This is because, for example, a transport task involving the container configured to contain a photoresist mask is typically generated less frequently than a transport task involving the container configured to contain a semiconductor substrate. As in this structure, when the first article is the container configured to contain a semiconductor substrate and the second article is the container configured to contain a photoresist mask, installing the path power feeder in the second transport area tends to be expensive for the fewer second transport vehicles (or comparatively expensive). This is because, for example, the layout of the transport path for the container configured to contain a photoresist mask tends to be more complex than the layout of the transport path for the container configured to contain a semiconductor substrate.

In this manner, when the first article is the container configured to contain a semiconductor substrate and the second article is the container configured to contain a photoresist mask, the second transport vehicles tend to be fewer than the first transport vehicles, and the cost of installing the path power feeder in the second transport area tends to be higher. With the technique according to one or more embodiments of the present disclosure, the second transport vehicles are to include the power storages. However, the path power feeder in the second transport area can be downscaled compared with the path power feeder in a structure in which the entire second transport area includes the path power feeder. In this structure with the above tendencies, the transport facility can be less costly with the cost reduction resulting from downscaling the path power feeder exceeding the cost increase resulting from installing the power storage on the second transport vehicle. The technique according to one or more embodiments of the present disclosure may thus be particularly suitable for a structure in which the first article is the container configured to contain a semiconductor substrate and the second article is the container configured to contain a photoresist mask as in this structure.

The transport facility according to one or more embodiments of the present disclosure produces at least one of the effects described above.

What is claimed is:

1. A transport facility, comprising:
at least one first transport vehicle configured to transport a first article;
at least one second transport vehicle configured to transport a second article different from the first article;
a first transport area in which the at least one first transport vehicle travels to transport the first article;
a second transport area in which the at least one second transport vehicle travels to transport the second article; and
a path power feeder extending along a travel path for the at least one first transport vehicle or the at least one second transport vehicle, the path power feeder being configured to feed power to the at least one first transport vehicle or the at least one second transport vehicle on the travel path, and
wherein:
the path power feeder is present in the first transport area and absent in at least a part of the second transport area,
the at least one first transport vehicle is configured to travel using electric power fed from the path power feeder, and
the at least one second transport vehicle is configured to travel in both the first transport area and the second transport area and receive electric power from the path power feeder, the at least one second transport vehicle comprising a power storage configured to store electric power fed from the path power feeder, the at least one second transport vehicle being configured to travel in the second transport area using the electric power stored in the power storage.

2. The transport facility according to claim 1, further comprising:
a control system configured to control the at least one second transport vehicle, and
wherein the control system performs:
a task assignment process for assigning to the at least one second transport vehicle a transport task specifying a source of the second article and a destination of the second article, and
a charge process for causing the at least one second transport vehicle to which no transport task has been assigned to move to a site in which the path power feeder is present and causing the path power feeder to charge the power storage.

3. The transport facility according to claim 2, wherein:
the first transport area comprises a standby section for the at least one second transport vehicle to wait, and
the control system causes the at least one second transport vehicle to which no transport task has been assigned to move to the standby section in the charge process.

4. The transport facility according to claim 2, wherein:
the control system determines whether a battery level of the power storage is higher than or equal to a set value, and causes the at least one second transport vehicle to which no transport task has been assigned to wait at the part of the second transport area in response to determining that the battery level of the power storage in the at least one second transport vehicle to which no transport task has been assigned is higher than or equal to the set value.

5. The transport facility according to claim 1, wherein:
the at least one first transport vehicle comprises a plurality of first transport vehicles, and the at least one second transport vehicle comprises a plurality of second transport vehicles, and
a value resulting from dividing a second travel path length by a number of the plurality of second transport vehicles is greater than a value resulting from dividing a first travel path length by a number of the plurality of first transport vehicles, where the first travel path length is a total length of the travel path for the plurality of first transport vehicles in the first transport area, and the second travel path length is a total length of the travel path for the plurality of second transport vehicles in the second transport area.

6. The transport facility according to claim 1, wherein:
the at least one first transport vehicle comprises a plurality of first transport vehicles, and the at least one second transport vehicle comprises one or more second transport vehicles, and
the one or more second transport vehicles are fewer than the plurality of first transport vehicles.

7. The transport facility according to claim 1, wherein:
a second travel path length is shorter than a first travel path length, where the first travel path length is a total length of the travel path for the at least one first transport vehicle in the first transport area, and the second travel path length is a total length of the travel path for the at least one second transport vehicle in the second transport area.

8. The transport facility according to claim 1, wherein:
the first article is a container configured to contain a semiconductor substrate, and
the second article is a container configured to contain a photoresist mask for use to process the semiconductor substrate.
